(19) United States
(12) Patent Application Publication
(10) Pub. No.: US 2024/0234593 A1
(43) Pub. Date: Jul. 11, 2024

(54) LIGHT-RECEIVING ELEMENT AND LIGHT DETECTION DEVICE

(71) Applicant: Sumitomo Electric Industries, Ltd., Osaka (JP)

(72) Inventor: Kazutoshi Natsume, Osaka-shi (JP)

(73) Assignee: Sumitomo Electric Industries, Ltd., Osaka (JP)

(21) Appl. No.: 18/528,260

(22) Filed: Dec. 4, 2023

(30) Foreign Application Priority Data
Jan. 11, 2023 (JP) 2023-002714

(51) Int. Cl. H01L 31/02; H01L 31/0232; H01L 31/0236

(52) U.S. Cl. CPC H01L 31/02002; H01L 31/02327; H01L 31/02363

(57) ABSTRACT

A light-receiving element includes a substrate having a first main surface, a first contact layer of a first conductivity type disposed on the first main surface, a light receiving layer disposed on the first contact layer, a pixel separation adjusting layer disposed on the light receiving layer, a second contact layer of a second conductivity type disposed on the pixel separation adjusting layer, a second groove formed in the second contact layer, the pixel separation adjusting layer and the light receiving layer outside the first grooves in a first direction parallel to the first main surface and reaching the first contact layer, a first electrode contacting the first contact layer at the bottom of the second groove, and a second electrode disposed on the second contact layer, a first region having a first electric resistance, and a second region having a second electric resistance higher than the first electric resistance.

### CROSS REFERENCE TO RELATED APPLICATIONS

This application claims priority based on Japanese Patent Application No. 2023-002714 filed on Jan. 11, 2023, and the entire contents of the Japanese patent application are incorporated herein by reference.

### TECHNICAL FIELD

The present disclosure relates to a light-receiving element and a light detection device.

### BACKGROUND

As a light-receiving element for detecting infrared rays, the light-receiving element in which a groove for pixel separation is formed in a semiconductor layer provided on a light-receiving layer is disclosed.

### PTL 1: Japanese Unexamined Patent Application Publication No. 2021-034644

### SUMMARY

A light-receiving element according to the present disclosure includes a substrate having a first main surface; a first contact layer provided on the first main surface, the first contact layer being of a first conductivity type; a light receiving layer provided on the first contact layer; a pixel separation adjusting layer provided on the light receiving layer; a second contact layer provided on the pixel separation adjusting layer, the second contact layer being of a second conductivity type; a plurality of first grooves separating the second contact layer and the pixel separation adjusting layer into a plurality of pixels in a first direction parallel to the first main surface; a second groove formed in the second contact layer, the pixel separation adjusting layer, and the light receiving layer on an outer side of the plurality of first grooves in the first direction, the second groove reaching the first contact layer; a first electrode in contact at a bottom of the second groove with the first contact layer; and a second electrode provided on the second contact layer. The light receiving layer has a first region provided for each of the pixels, the first region having a first electric resistance. The light-receiving element has a second region provided between the first regions adjacent to each other, the second region having a second electric resistance higher than the first electric resistance.

### BRIEF DESCRIPTION OF THE DRAWINGS

FIG. 1 is a schematic diagram illustrating a light-receiving element according to a first embodiment.

FIG. 2 is a cross-sectional view illustrating a light-receiving element according to a first embodiment.

FIG. 3 is a cross-sectional view (part 1) illustrating a method for manufacturing a light-receiving element according to a first embodiment.

FIG. 4 is a cross-sectional view (part 2) illustrating a method for manufacturing a light-receiving element according to a first embodiment.

FIG. 5 is a cross-sectional view (part 3) illustrating a method for manufacturing a light-receiving element according to a first embodiment.

FIG. 6 is a cross-sectional view (part 4) illustrating a method for manufacturing a light-receiving element according to a first embodiment.

FIG. 7 is a cross-sectional view (part 5) illustrating a method for manufacturing a light-receiving element according to a first embodiment.

FIG. 8 is a cross-sectional view (part 6) illustrating a method for manufacturing a light-receiving element according to a first embodiment.

FIG. 9 is a cross-sectional view (part 7) illustrating a method for manufacturing a light-receiving element according to a first embodiment.

FIG. 10 is a cross-sectional view (part 8) illustrating a method for manufacturing a light-receiving element according to a first embodiment.

FIG. 11 is a cross-sectional view (part 9) illustrating a method for manufacturing a light-receiving element according to a first embodiment.

FIG. 12 is a cross-sectional view illustrating a light-receiving element according to a reference example.

FIG. 13 is a cross-sectional view illustrating a light-receiving element according to a second embodiment.

FIG. 14 is a cross-sectional view illustrating a light detection device according to a third embodiment.

### DETAILED DESCRIPTION

It is desirable to improve detection accuracy for light-receiving elements.

It is an object of the present disclosure to provide a light-receiving element and a light detection device capable of improving detection accuracy.

### Description of Embodiments of Present Disclosure

First, embodiments of the present disclosure will be listed and explained.

[1] A light-receiving element according to the embodiment of the present disclosure includes a substrate having a first main surface; a first contact layer provided on the first main surface, the first contact layer being of a first conductivity type; a light receiving layer provided on the first contact layer; a pixel separation adjusting layer provided on the light receiving layer; a second contact layer provided on the pixel separation adjusting layer, the second contact layer being of a second conductivity type; a plurality of first grooves separating the second contact layer and the pixel separation adjusting layer into a plurality of pixels in a first direction parallel to the first main surface; a second groove formed in the second contact layer, the pixel separation adjusting layer, and the light receiving layer on an outer side of the plurality of first grooves in the first direction, the second groove reaching the first contact layer; a first electrode in contact at a bottom of the second groove with the first contact layer; and a second electrode provided on the second contact layer. The light receiving layer has a first region provided for each of the pixels, the first region having a first electric resistance. The light-receiving element has a second region provided between the first regions adjacent to each other, the second region having a second electric resistance higher than the first electric resistance.

When light is incident on the light receiving layer, electric charges are generated in the light receiving layer, and the electric charges flow toward the first contact layer or the second contact layer in accordance with a potential difference between the first contact layer and the second contact layer in each pixel. At this time, since the second electric resistance is higher than the first electric resistance, it is difficult for the electric charges to pass through the second region, and the electric charges flow toward the first contact layer or the second contact layer inside the first region. In addition, since the electric charges are less likely to occur in the second region, it is possible to reduce the occurrence of a delay in electrical response to the light signal due to movement of the electric charges from the second region to the first region. Therefore, an electric charge corresponding to the amount of light incident on each of the pixels is easily obtained, and high detection accuracy is obtained.

[2] In [1], the second region may have a width of 1 μm to 5 μm. In this case, it is easy to form the second region, and it is easy to allocate a sufficient size of the first region.

[3] In [1] or [2], the second region may include third grooves each being continuous with a bottom surface of a corresponding one of the first grooves and extending into the light receiving layer. In this case, light is not absorbed in the third grooves, and it is possible to eliminate a decrease in detection accuracy accompanying the generation of the electric charges in the vicinity of the boundary between adjacent pixels.

[4] In [3], the light-receiving element may have a reflection film provided inside of each of the third grooves and configured to reflect, toward the first regions, light transmitted through the second region. When the light transmitted through the second region is reflected outside the light-receiving element and returns to the light-receiving layer, the pixel on which the light is incident may not be identified and the detection accuracy may decrease. By reflecting the light by the reflection film, the pixel on which the light is incident may be identified and the decrease in the detection accuracy may be eliminated.

[5] In [3], the light-receiving element may have an absorption film provided inside of each of the third grooves and configured to absorb light transmitted through the second region. When the light transmitted through the second region is reflected outside the light-receiving element and returns to the light-receiving layer, the pixel on which the light is incident may not be identified and the detection accuracy may decrease. However, by absorbing the light by the absorption film, the decrease in the detection accuracy due to the reflected light may be reduced.

[6] In any one of [3] to [5], the third grooves may reach the first contact layer. In this case, it is particularly easy to improve the detection accuracy.

[7] In [1], the second region may include an impurity region containing an impurity at a higher concentration than the first regions. In this case, although light is absorbed by the impurity region, the movement of the electric charges from the impurity region to the first region is reduced, and it is possible to eliminate a decrease in detection accuracy accompanying the generation of the electric charges in the vicinity of the boundary between adjacent pixels.

[8] In [7], the light-receiving element may include fourth grooves each being continuous with a bottom surface of a corresponding one of the first grooves and reaching the impurity region. In this case, light is not absorbed in the fourth grooves, and it is easy to further eliminate a decrease in detection accuracy accompanying the generation of the electric charges in the vicinity of the boundary between adjacent pixels.

[9] A light detection device according to another aspect of the present disclosure includes the light-receiving element according to any one of [1] to [8]; and a circuit board connected to the light-receiving element. When the light detection device includes the light-receiving element, the detection accuracy can be improved.

[10] In [9], the light detection device may have a resin layer provided between the light-receiving element and the circuit board. In this case, when the light transmitted through the second region is reflected outside the light-receiving element and returns to the light-receiving layer, the pixel on which the light is incident may not be identified and the detection accuracy may decrease. However, since the light transmitted through the second region is absorbed by the resin layer, the decrease in the detection accuracy due to the reflected light may be eliminated.

### Details of Embodiments of Present Disclosure

Embodiments of the present disclosure will be described in detail, but the present disclosure is not limited thereto. In this specification and the drawings, constituent elements having substantially the same functional configuration are denoted by the same reference numerals, and redundant description thereof may be omitted. In addition, although an XYZ orthogonal coordinate system is used in the following description, the coordinate system is defined for description and does not limit the attitude of the light-receiving element or the light detection device. In addition, when viewed from an arbitrary point, a +Z side may be referred to as an upper side, and a −Z side may be referred to as a lower side.

### First Embodiment

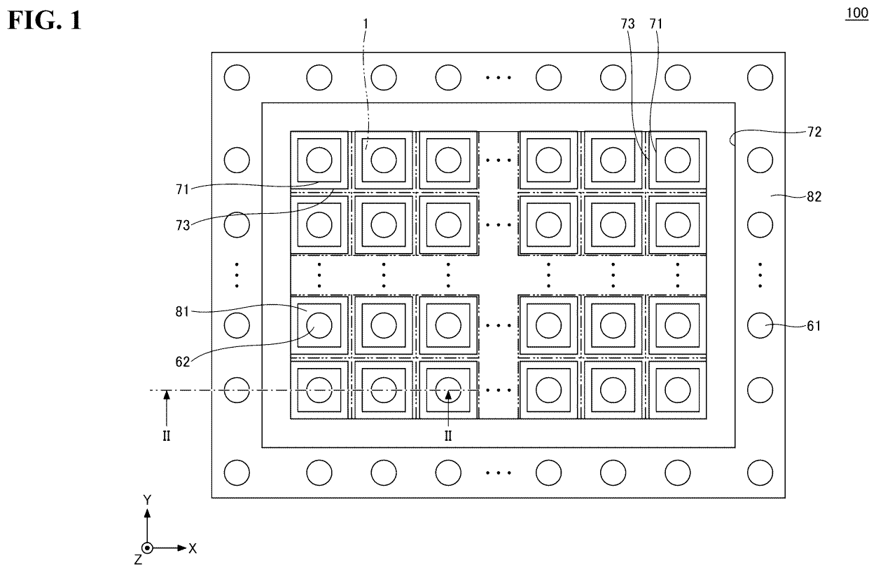

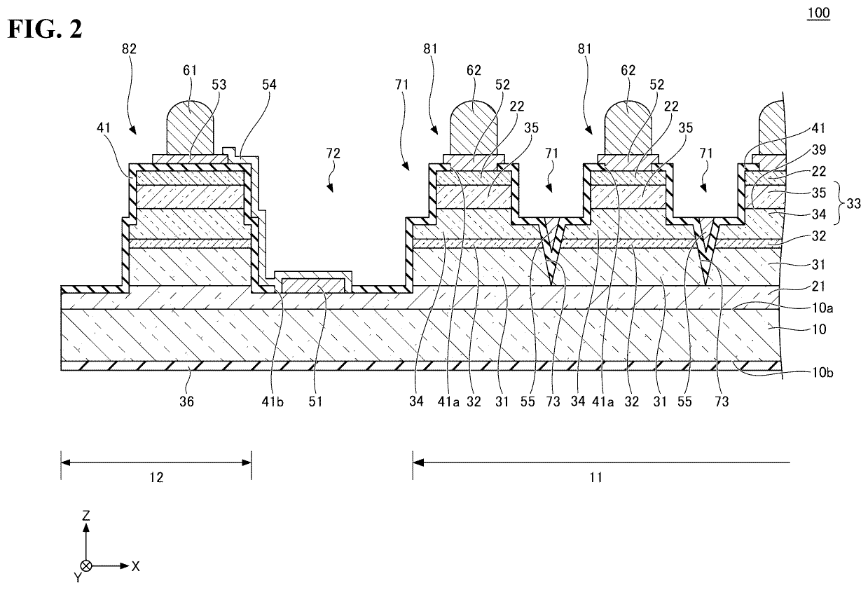

A first embodiment will be described. The first embodiment relates to a light-receiving element. FIG. 1 is a schematic diagram illustrating a light-receiving element according to the first embodiment. FIG. 2 is a cross-sectional view of a light-receiving element according to the first embodiment. FIG. 1 shows the arrangement of mesas, bumps and grooves in a plan view. FIG. 2 corresponds to a cross-sectional view taken along line II-II in FIG. 1.

A light-receiving element 100 according to the first embodiment is formed with a plurality of pixels 1 constituting a two dimensional array. For example, the pitch of pixel 1 is 25 μm to 85 μm. In addition, 32×128 pixels of pixel 1 may be formed, 256×320 pixels of pixel 1 may be formed, or 512×640 pixels of pixel 1 may be formed by “the number in the X-axis direction”×“the number in the Y-axis direction”.

As shown in FIG. 1, light-receiving element 100 includes a substrate 10, an n-type contact layer 21, a light receiving layer 31, an intermediate layer 32, a pixel separation adjusting layer 33, and a p-type contact layer 22. Light-receiving element 100 further includes a passivation film 41, an anti-reflection film 36, a p-electrode 52, a first n-electrode 51, a second n-electrode 53, a wire 54, a metal film 55, an indium (In) bump 61, and an In-bump 62.

Substrate 10 is, for example, an n-type indium phosphide (InP) substrate. Substrate 10 contains, for example, iron (Fe). Substrate 10 has a first main surface 10a and a second main surface 10b opposite to first main surface 10a. The thickness of substrate 10 is, for example, about 600 μm.

N-type contact layer 21 is provided on first main surface 10a. N-type contact layer 21 is, for example, an n-type InP layer. The thickness of n-type contact layer 21 is, for example, about 2.0 μm. N-type contact layer 21 contains, for example, silicon (Si) at a concentration of 1×10¹⁸ cm⁻³ or more. N-type contact layer 21 is an example of a first contact layer.

Light receiving layer 31 is provided on n-type contact layer 21. Light receiving layer 31 is, for example, an indium gallium arsenide (InGaAs) layer. Light receiving layer 31 has, for example, a thickness of about 2.0 μm. Light receiving layer 31 may have a thickness of 1.0 μm to 4.0 μm. Light receiving layer 31 is not doped with an impurity element, and the concentration of the impurity element contained in light receiving layer 31 is 1×10¹⁵ cm⁻³ or less.

Intermediate layer 32 is provided on light receiving layer 31. Intermediate layer 32 includes, for example, an indium gallium arsenide phosphide (InGaAsP) layer. Intermediate layer 32 has, for example, a thickness of about 0.05 μm. Intermediate layer 32 is not doped with an impurity element, and the concentration of the impurity element contained in intermediate layer 32 is 2×10¹⁵ cm⁻³ or less. The bandgap of intermediate layer 32 is wider than the bandgap of light receiving layer 31 and narrower than the bandgap of pixel separation adjusting layer 33. Intermediate layer 32 may include a plurality of InGaAsP layers having different compositions. In this case, among the plurality of InGaAsP layers, an InGaAsP layer closer to intermediate layer 32 has a narrower band gap. That is, among the plurality of InGaAsP layers, the band gap becomes wider in a stepwise manner as the distance from intermediate layer 32 increases.

Pixel separation adjusting layer 33 is provided on intermediate layer 32. Pixel separation adjusting layer 33 includes an n-type wide gap layer 34 and a p-type wide gap layer 35. N-type wide gap layer 34 is provided on intermediate layer 32, and p-type wide gap layer 35 is provided on n-type wide gap layer 34. N-type wide gap layer 34 is, for example, an n-type InP layer. N-type wide gap layer 34 have, for example, a thickness of about 0.5 μm. N-type wide gap layer 34 may have a thickness of 0.2 μm to 1.0 μm. N-type wide gap layer 34 contains, for example, Si at a concentration of 2×10¹⁵ cm⁻³ or less. P-type wide gap layer 35 is, for example, a p-type InP layer. P-type wide gap layer 35 have, for example, a thickness of about 0.2 μm. P-type wide gap layer 35 may have a thickness of 0.1 μm to 0.5 μm. P-type wide gap layer 35 contains, for example, Zn at a concentration of 1×10¹⁸ cm⁻³ or more. There is a pn junction 39 at the interface between n-type wide gap layer 34 and p-type wide gap layer 35. The band gap of n-type wide gap layer 34 and the band gap of p-type wide gap layer 35 are wider than the band gap of intermediate layer 32 and the band gap of light receiving layer 31.

P-type contact layer 22 is provided on p-type wide gap layer 35. P-type contact layer 22 is, for example, a p-type InGaAs layer. P-type contact layer 22 contains, for example, Zn at a concentration of 2×10¹⁹ cm⁻³ to 6×10¹⁹ cm⁻³. P-type contact layer 22 is, for example, a thickness of about 0.2 μm. P-type contact layer 22 may have a thickness of 0.1 μm to 0.5 μm. P-type contact layer 22 is an example of a second contact layer.

A plurality of first grooves 71 are formed in p-type contact layer 22, p-type wide gap layer 35, and a part of n-type wide gap layer 34. First groove 71 reaches n-type wide gap layer 34. N-type wide gap layer 34 is exposed on the bottom surface of first groove 71. First groove 71 penetrates through pn junction 39. A mesa 81 is formed for each pixel 1, and the pixels are separated by first groove 71. A part of first groove 71 is formed at a constant pitch in the X-axis direction and extends in the Y-axis direction. Another part of first groove 71 is formed at a constant pitch in the Y-axis direction and extends in the X-axis direction. First groove 71 divides p-type contact layer 22 and pixel separation adjusting layer 33 into a plurality of pixels 1 in the X-axis direction or the Y-axis direction parallel to first main surface 10a. For example, first groove 71 has a depth of 0.6 μm to 0.8 μm, and a width of 5 μm to 10 μm. The planner shape of mesa 81 is, for example, a square shape with a side length of 20 μm to 75 μm.

Outside the plurality of first grooves 71 in the X-axis direction or the Y-axis direction, a second groove 72 is formed in p-type contact layer 22, p-type wide gap layer 35, n-type wide gap layer 34, intermediate layer 32, light receiving layer 31 and a part of n-type contact layer 21. Second groove 72 reaches n-type contact layer 21. N-type contact layer 21 is exposed on the bottom surface of second groove 72. Second groove 72 is formed in a frame shape in a plan view perpendicular to first main surface 10a, and surrounds all first grooves 71. A pixel region 11 and an electrode connection region 12 are separated from each other by second groove 72. Mesa 81 is formed in pixel region 11. A mesa 82 is formed in electrode connection region 12. Second groove 72 has, for example, a width of about 450 μm.

Third grooves 73 each being continuous with the bottom surface of a corresponding one of first groove 71 are formed between adjacent mesas 81. Third groove 73 is formed in n-type wide gap layer 34, intermediate layer 32, and light receiving layer 31. Third groove 73 enters into light receiving layer 31. For example, third groove 73 reaches n-type contact layer 21. For example, the cross-sectional shape of third groove 73 is a V shape. A part of third groove 73 is formed at a constant pitch in the X-axis direction and extends in the Y-axis direction. Another part of third groove 73 is formed at a constant pitch in the Y-axis direction and extends in the X-axis direction. Third groove 73 is located at a boundary between adjacent pixels 1. Third groove 73 at the top surface of light receiving layer 31 has, for example, a width of 1 μm to 5 μm. The width of third groove 73 at the top surface of light receiving layer 31 can be measured using, for example, an electron microscope.

The region defined by third groove 73 of light receiving layer 31 has a first electric resistance corresponding to the material of light receiving layer 31. The region defined by third groove 73 of light receiving layer 31 is an example of a first region. In addition, no current substantially flows through third groove 73, and third groove 73 has a second electric resistance higher than the first electric resistance. Third groove 73 is an example of a second region.

Passivation film 41 covers p-type contact layer 22, p-type wide gap layer 35, n-type wide gap layer 34, intermediate layer 32, light receiving layer 31, n-type contact layer 21, and substrate 10. Passivation film 41 is, for example, a silicon nitride (SiN) film. Passivation film 41 has, for example, a thickness of 180 nm to 220 nm. An opening portion 41a exposing p-type contact layer 22 of mesa 81 and an opening portion 41b exposing n-type contact layer 21 between pixel region 11 and electrode connection region 12 are formed in passivation film 41. A side surface of pn junction 39 is in contact with passivation film 41.

In each mesa 81, p-electrode 52 is formed on p-type contact layer 22. P-electrode 52 contacts p-type contact layer 22 through opening portion 41a. P-electrode 52 is configured by a metal laminated film in which, for example, a titanium (Ti) layer and a platinum (Pt) layer are sequentially laminated. For example, the Ti layer has a thickness of about 50 nm and the Pt layer has a thickness of about 80 nm. P-electrode 52 is an example of a second electrode.

First n-electrode 51 is formed on n-type contact layer 21 between pixel region 11 and electrode connection region 12. First n-electrode 51 is in contact with n-type contact layer 21 through opening portion 41b. Second n-electrode 53 is, on mesa 82, formed on passivation film 41. First n-electrode 51 and second n-electrode 53 are formed of a metal laminated film in which, for example, a Ti layer and a Pt layer are sequentially laminated. For example, the Ti layer has a thickness of about 50 nm and the Pt layer has a thickness of about 80 nm. First n-electrode 51 is an example of a first electrode.

Wire 54 connects first n-electrode 51 and second n-electrode 53. Wire 54 is formed on passivation film 41. Wire 54 is formed of, for example, a metal laminated film in which a Ti layer and a gold (Au) layer are sequentially laminated. For example, the Ti-layer has a thickness of about 50 nm and the Au-layer has a thickness of about 600 nm.

Metal film 55 overlaps third groove 73 in a plan view perpendicular to first main surface 10a, and is formed on passivation film 41. Metal film 55 may be formed inside third groove 73. Metal film 55 is made of, for example, the same material as p-electrode 52. Metal film 55 is an example of a reflection film.

In-bump 62 is provided on p-electrode 52. In each pixel 1 in pixel region 11, p-electrode 52 having a circular planar shape is formed on the upper surface of mesa 81, and In-bump 62 having a circular planar shape is formed on p-electrode 52.

In electrode connection region 12, In-bump 61 is provided on second n-electrode 53. In-bump 61 having a circular planar shape is formed on second n-electrode 53.

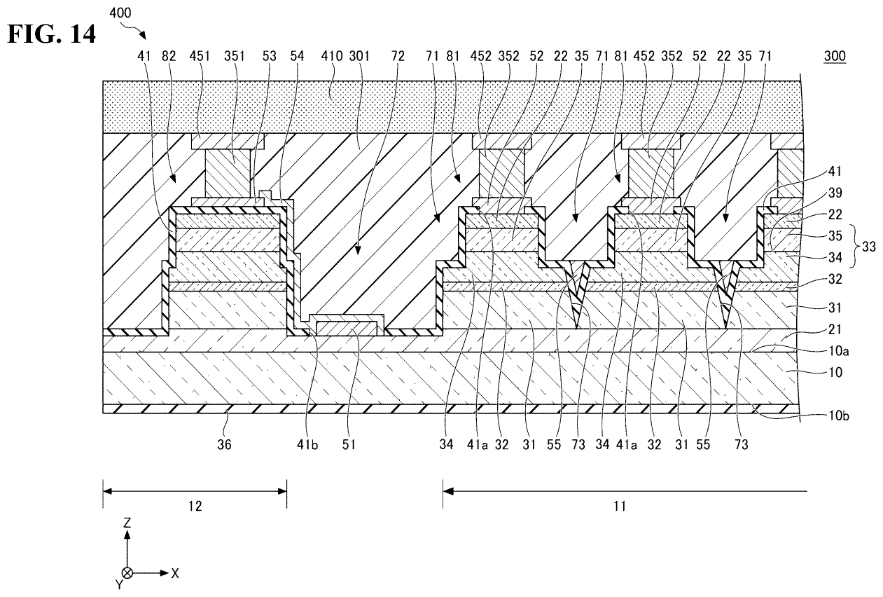

Second n-electrode 53 and p-electrode 52 are connected to electrodes provided on a readout circuit board 400 (see FIG. 14) via In-bumps 61 and 62, respectively. In-bumps 61 and 62 have, for example, a height of about 10 μm.

Anti-reflection film 36 is provided on second main surface 10b. Anti-reflection film 36 is, for example, an SiN film.

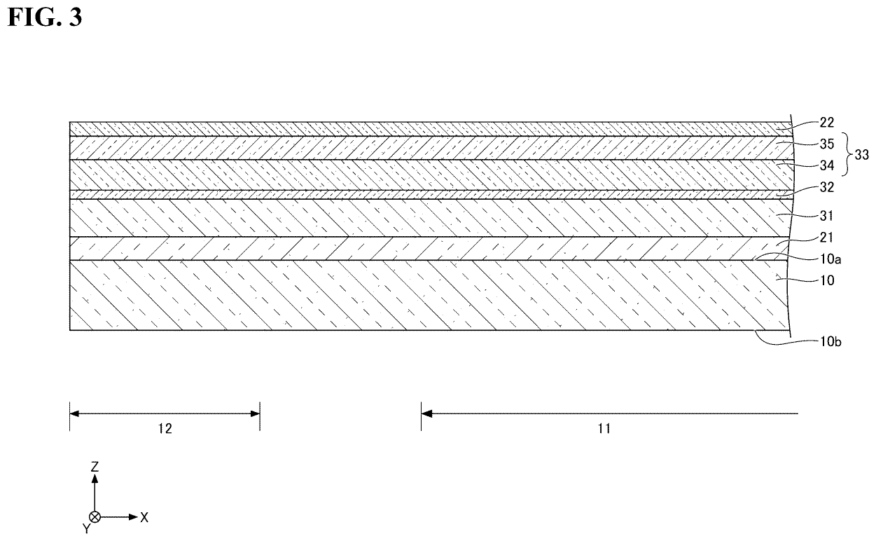

Next, a method for manufacturing light-receiving element 100 according to the first embodiment will be described. FIGS. 3 to 11 are cross-sectional views illustrating a method for manufacturing a light-receiving element according to the first embodiment.

First, as shown in FIG. 3, n-type contact layer 21, light receiving layer 31, intermediate layer 32, n-type wide gap layer 34, p-type wide gap layer 35 and p-type contact layer 22 are sequentially formed on first main surface 10a of substrate 10 by epitaxial growth. For the epitaxial growth of the compound semiconductor layer, a metal organic vapor phase epitaxy (MOVPE) method is used. Substrate 10 has, for example, a thickness of 400 μm to 500 μm.

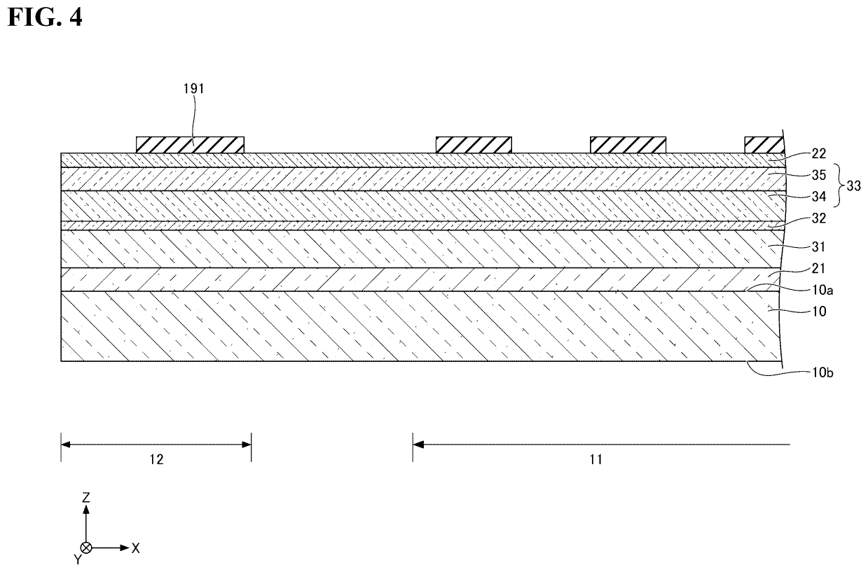

Next, as shown in FIG. 4, an SiN film 191 having a thickness of about 0.4 μm is formed on p-type contact layer 22 by a plasma chemical vapor deposition (CVD) method. Next, a photoresist is applied onto SiN film 191, and exposure light by an exposure light device and development are performed to form a resist pattern (not shown). The resist pattern has an opening portion in a region where first groove 71 is formed and a region where second groove 72 is formed. SiN film 191 in the opening portion of the resist pattern is removed by wet etching using buffered hydrofluoric acid, thereby forming a mask from SiN film 191. Thereafter, the resist pattern is removed by an organic solvent or the like.

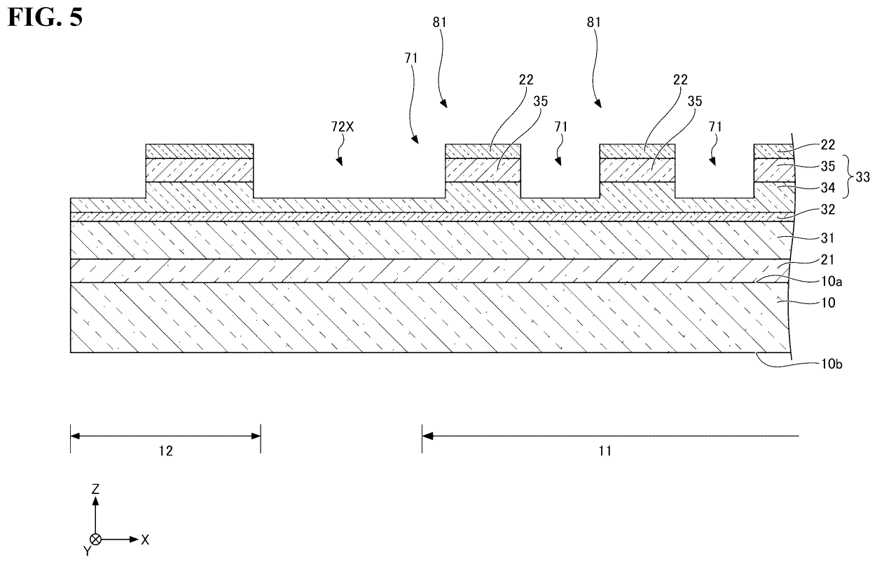

Next, as shown in FIG. 5, p-type contact layer 22, p-type wide gap layer 35, and a part of n-type wide gap layer 34 exposed in the opening portion of SiN film 191 are removed by dry etching such as reactive ion etching (RIE). In this RIE, a mixture gas of, for example, silicon tetrachloride (SiCl₄) gas and argon (Ar) gas is used. In this way, first groove 71 for pixel separation is formed. Also, a temporary groove 72X is formed in a region where second groove 72 is formed. Along with the formation of first groove 71, mesa 81 is formed and each pixel 1 (see FIG. 1) is separated.

Next, deposits (not shown) generated by the dry etching are removed. The deposits can be removed using buffered hydrofluoric acid. In addition, damage may occur in the vicinity of first groove 71 of p-type contact layer 22, p-type wide gap layer 35, and n-type wide gap layer 34 during dry etching. Therefore, after the removal of the deposit, wet etching is performed to remove the portion damaged during dry etching. For example, a portion of each of p-type contact layer 22, p-type wide gap layer 35, and n-type wide gap layer 34 exposed to first groove 71 is removed by a thickness of 0.1 μm. Thereafter, SiN film 191 is removed by buffered hydrofluoric acid.

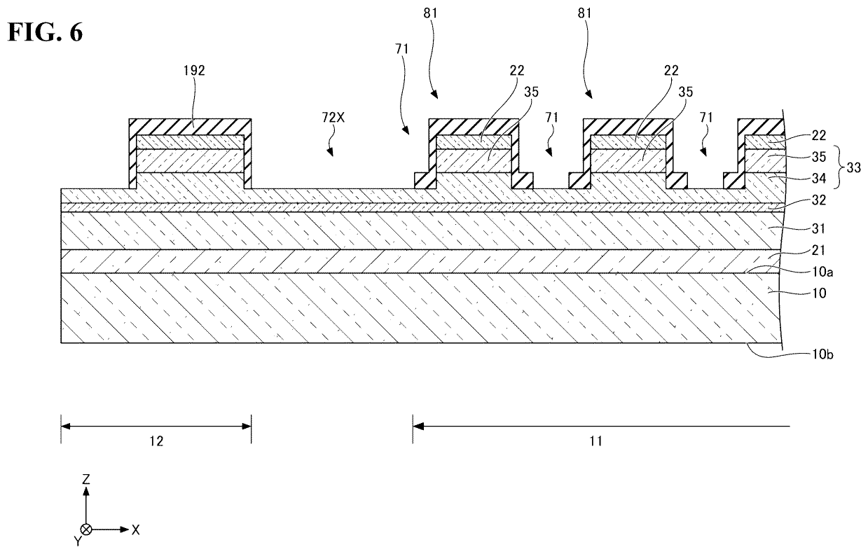

Next, as shown in FIG. 6, an SiN film 192 having a thickness of about 0.8 μm is formed by a plasma CVD method so as to cover p-type contact layer 22, p-type wide gap layer 35 and n-type wide gap layer 34. Next, a photoresist is applied onto SiN film 192, and exposure light by an exposure light device and development are performed to form a resist pattern (not shown). The resist pattern has opening portions in a region where second groove 72 is formed and a region where third groove 73 is formed. SiN film 192 in the opening portion of the resist pattern is removed by wet etching using buffered hydrofluoric acid, thereby forming a mask from SiN film 192. Thereafter, the resist pattern is removed by an organic solvent or the like.

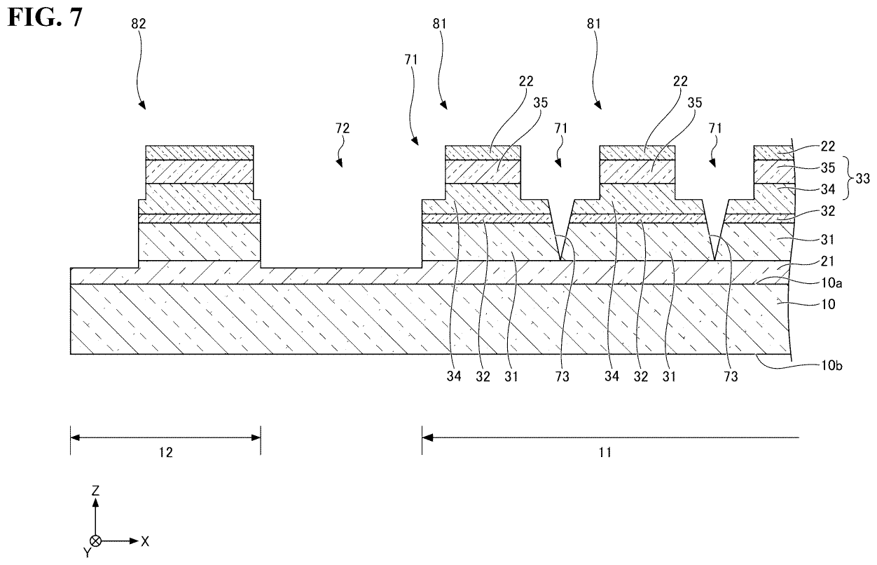

Next, as shown in FIG. 7, n-type wide gap layer 34, intermediate layer 32, light receiving layer 31, and a part of n-type contact layer 21 exposed in the opening portion of SiN film 192 are removed by dry etching such as RIE. In this RIE, for example, a mixture gas of SiCl₄ gas and Ar gas is used. In this way, second grooves 72 and third grooves 73 are formed, and mesa 82 is formed outside second groove 72 when viewed from mesa 81. In addition, third grooves 73 each being continuous with the bottom surface of a corresponding one of a corresponding one of first grooves 71 are formed.

Next, deposits (not shown) generated by the dry etching are removed. The deposits can be removed using buffered hydrofluoric acid. In addition, damage may occur in the vicinity of second groove 72 or third groove 73 of n-type wide gap layer 34, intermediate layer 32, light receiving layer 31, and n-type contact layer 21 during dry etching. Therefore, after the removal of the deposit, wet etching is performed to remove the portion damaged during dry etching. For example, a portion of each of n-type wide gap layer 34, intermediate layer 32, light receiving layer 31, and n-type contact layer 21 exposed to second groove 72 or third groove 73 is removed by a thickness of 0.1 μm. Thereafter, SiN film 192 is removed by buffered hydrofluoric acid.

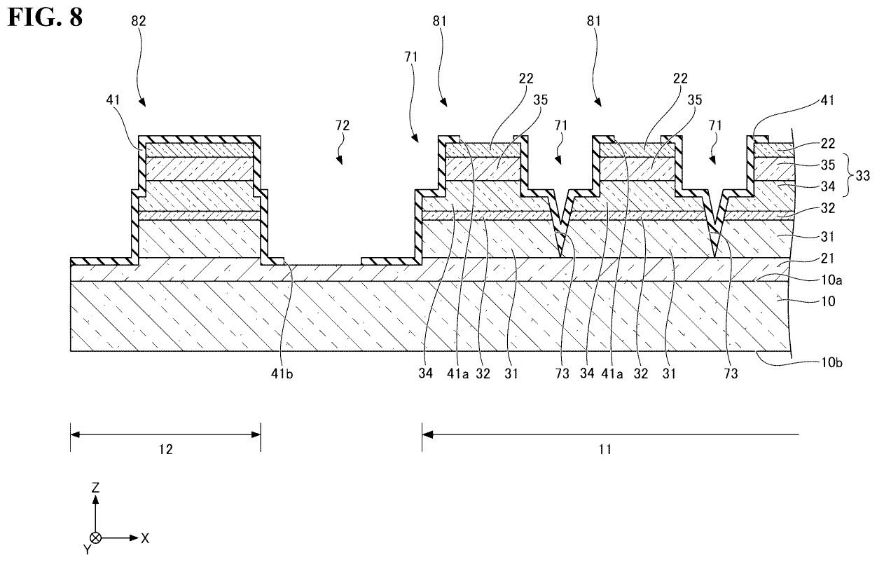

Next, as shown in FIG. 8, passivation film 41 is formed. Specifically, a SiN film (not shown) is formed on the entire surface by a plasma CVD method, a photoresist is applied on the formed SiN film, exposure light by an exposure light device and development are performed to form a resist pattern (not shown). The resist pattern has opening portions in a region where p-electrode 52 is formed and a region where first n-electrode 51 is formed, and the SiN film in the opening portion of the resist pattern is removed by dry etching such as RIE. As a result, passivation film 41 having opening portion 41a exposing the surface of p-type contact layer 22 of mesa 81 and opening portion 41b exposing the surface of n-type contact layer 21 is formed.

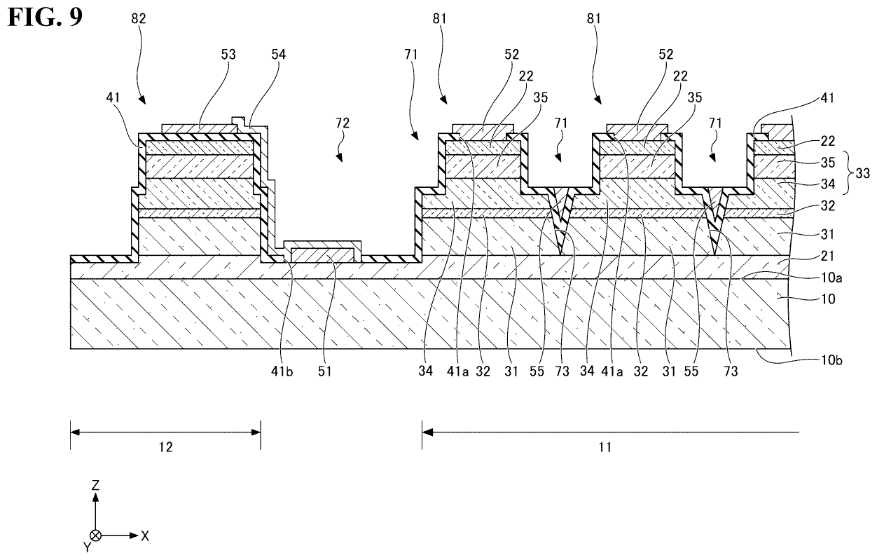

Next, as shown in FIG. 9, p-electrode 52 is formed on p-type contact layer 22, first n-electrode 51 is formed on n-type contact layer 21, and second n-electrode 53 is formed on mesa 82 and passivation film 41. In addition, metal film 55 is formed on passivation film 41 so as to overlap third groove 73 in a plan view perpendicular to first main surface 10a. Metal film 55 is formed, for example, inside third groove 73. P-electrode 52, first n-electrode 51, second n-electrode 53, and metal film 55 are formed by a lift-off method. Specifically, a resist pattern (not shown) having opening portions is formed in a region where p-electrode 52 is to be formed, a region where first n-electrode 51 is to be formed, a region where second n-electrode 53 is to be formed, and a region where metal film 55 is to be formed. Next, a metal laminated film in which a Ti layer and a Pt layer are laminated in order is formed by electron beam (EB) vapor deposition, and is then immersed in an organic solvent or the like. As a result, the metal laminated film on the resist pattern is removed together with the resist pattern, and p-electrode 52, first n-electrode 51, second n-electrode 53 and metal film 55 are formed from the remaining metal laminated film.

Further, wire 54 connecting first n-electrode 51 and second n-electrode 53 is formed by a lift-off method. Specifically, a resist pattern (not shown) having an opening portion is formed in a region where wire 54 is to be formed, a metal laminated film in which a Ti layer and an Au layer are laminated in this order is formed by EB vapor deposition, and is then immersed in an organic solvent or the like. As a result, the metal laminated film on the resist pattern is removed together with the resist pattern, and wire 54 is formed from the remaining metal laminated film. The EB deposition for forming wire 54 is, for example, oblique deposition from a direction inclined from a direction perpendicular to first main surface 10a.

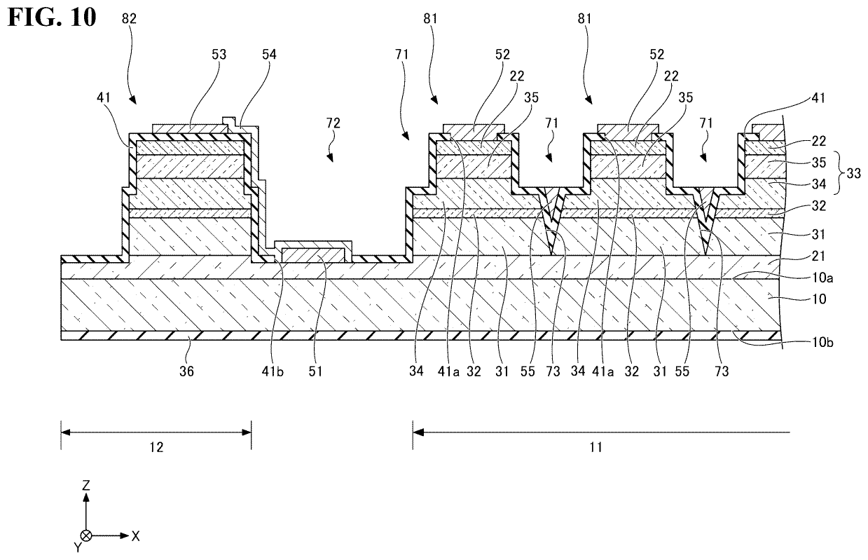

Next, as shown in FIG. 10, second main surface 10b of substrate 10 is polished to a mirror surface. Next, anti-reflection film 36 is formed on second main surface 10b. Anti-reflection film 36 is formed by a plasma CVD method.

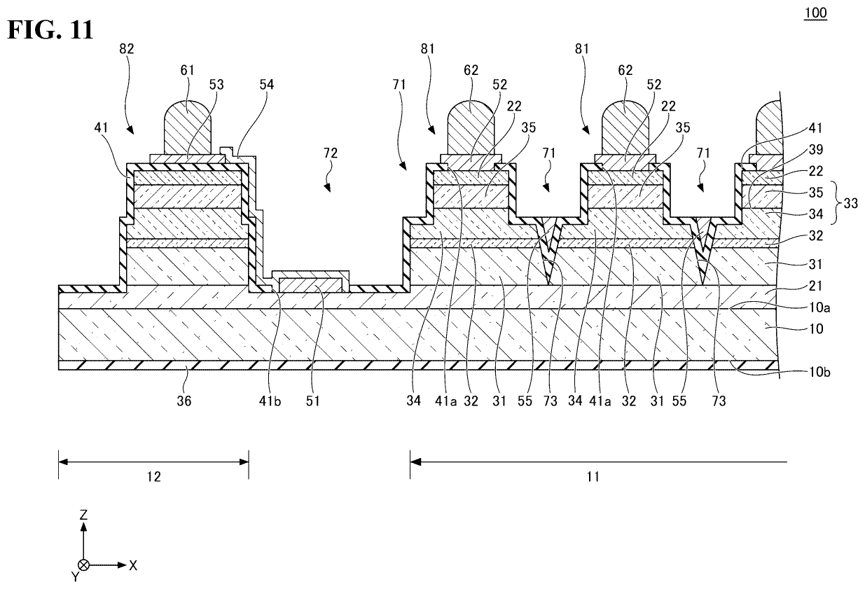

Next, as shown in FIG. 11, In-bump 61 is formed on second n-electrode 53, and In-bump 62 is formed on p-electrode 52. In-bumps 61 and 62 are formed by a lift-off method. Thereafter, it is divided into chips.

In this way, light-receiving element 100 according to the first embodiment can be manufactured.

Light-receiving element 100 is used by applying a reverse bias voltage of, for example, −8 V between p-electrode 52 and second n-electrode 53. When the reverse bias voltage is applied, a depletion layer spreads for each pixel 1. When near-infrared light is incident on light receiving layer 31 from second main surface 10b of substrate 10 in a state in which the depletion layer spreads for each pixel 1, electric charges (holes and electrons) are generated in light receiving layer 31, the electrons flow toward n-type contact layer 21, and the holes flow toward p-type contact layer 22. At this time, electric charges cannot pass through third groove 73, and holes flow toward p-type contact layer 22 inside a region (first region) defined by third groove 73 of light receiving layer 31.

In addition, the electric charges generated outside the depletion layer in light receiving layer 31 is more difficult to move than the electric charges generated in the depletion layer and may cause a delay in the electrical response to the light signal. However, since the electric charges are not generated in third groove 73, the occurrence of the delay can be reduced. The light incident on third groove 73 is reflected by metal film 55 toward light receiving layer 31 adjacent to third groove 73. Therefore, when metal film 55 is not provided, the light may be reflected in an unspecified direction by readout circuit board 400 (see FIG. 14), but the direction of the reflection is determined by the provision of metal film 55. Therefore, even if the incident light is excessive, multiple reflection is eliminated.

Further, as described above, p-electrode 52 is connected to the electrode provided on readout circuit board 400 (see FIG. 14) via In-bump 62, but a connection failure may occur in a certain In-bump 62. Even in such a case, since the electric charges generated in pixel 1 in which the connection failure occurs do not move to pixel 1 adjacent to the pixel 1, pixels 1 adjacent to the pixel 1 are not affected.

Therefore, according to light-receiving element 100, electric charges corresponding to the amount of light incident on each pixel 1 are easily obtained, and high detection accuracy is obtained.

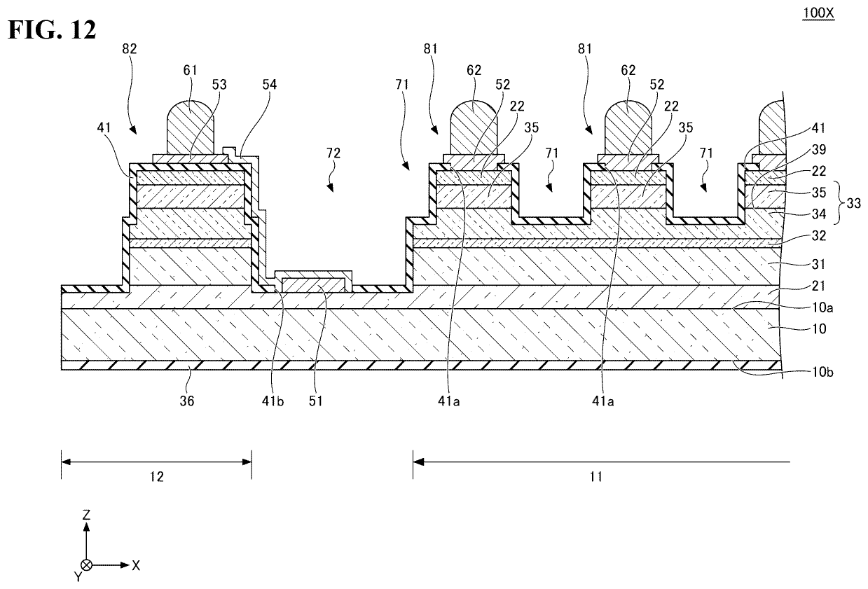

Here, a reference example will be described for comparison with the first embodiment. FIG. 12 is a cross-sectional view illustrating a light-receiving element according to a reference example. FIG. 12 corresponds to a cross-sectional view taken along line II-II in FIG. 1.

In a light-receiving element 100X according to the reference example, third groove 73 is not formed. Therefore, in light-receiving element 100X, the electric charges generated at the boundary between adjacent pixels 1 may cause a delay in the electrical response to the light signal. In addition, the electric charges generated at the boundary between adjacent pixels 1 may move to either pixel 1. Furthermore, when a connection failure occurs in one In-bump 62, the electric charges generated in pixel 1 in which the connection failure occurs may move to pixel 1 adjacent to the pixel 1. In this case, a large delay of the electrical response may occur.

Therefore, in light-receiving element 100X, electric charges corresponding to the amount of light incident on each pixel 1 are less likely to be obtained than in light-receiving element 100. In other words, according to light-receiving element 100, electric charges corresponding to the amount of light incident on each pixel 1 is more easily obtained than in light-receiving element 100X, and high detection accuracy is obtained.

When third groove 73 on the upper surface of light receiving layer 31 has a width of 1 μm to 5 μm, third groove 73 is easily formed, and a region (first region) of light receiving layer 31 in which light can be absorbed is easily allocated to a sufficient size. Third groove 73 on the upper surface of light receiving layer 31 may have a width of 1 μm to 3 μm or 1 μm to 2 μm.

Instead of metal film 55, an absorption film that absorbs light transmitted through third groove 73 may be provided. Since the absorption film absorbs light, the reflection in an unspecified direction by readout circuit board 400 (see FIG. 14) can be reduced. The absorption film is, for example, a resin film.

Third groove 73 does not need to reach n-type contact layer 21. However, since third groove 73 reaches n-type contact layer 21, it is easy to reduce the movement of the electric charges between adjacent pixels 1, and it is easy to reduce the generation of the electric charges in which pixel 1 of the movement destination is uncertain.

### Second Embodiment

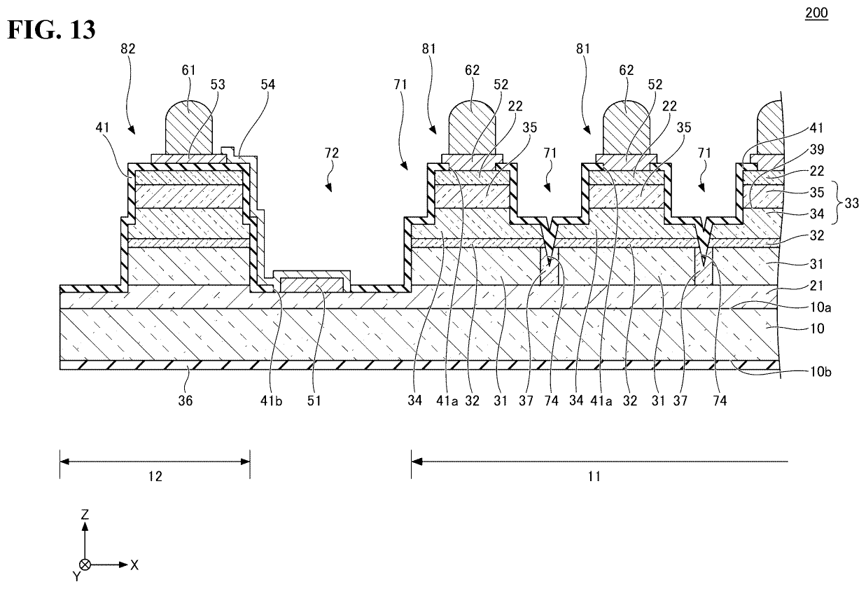

A second embodiment will be described. The second embodiment is different from the first embodiment in the configuration of the second region. FIG. 13 is a cross-sectional view illustrating a light-receiving element according to the second embodiment. FIG. 13 corresponds to a cross-sectional view taken along line II-II in FIG. 1.

In a light-receiving element 200, an impurity region 37 is formed in light receiving layer 31 between adjacent mesas 81. Impurity region 37 contains impurities, for example, iron (Fe), at a higher concentration than other regions of light receiving layer 31. Further, fourth grooves 74 each being continuous with the bottom surface of first grooves 71 are formed between adjacent mesas 81. Fourth groove 74 is formed in n-type wide gap layer 34, intermediate layer 32, and impurity region 37. Fourth groove 74 reaches impurity region 37. The depth of fourth groove 74 is such that impurity region 37 can sufficiently absorb light, and is, for example, 1 μm to 2 μm. For example, the cross-sectional shape of fourth groove 74 is a V shape. Impurity region 37 and a part of fourth groove 74 are formed at a constant pitch in the X-axis direction and extend in the Y-axis direction. Impurity region 37 and another part of fourth groove 74 are formed at a constant pitch in the Y-axis direction and extend in the X-axis direction. Impurity region 37 and fourth groove 74 are located at the boundary between adjacent pixels 1. Impurity region 37 has a width of 1 μm to 5 μm, for example. The width of impurity region 37 can be measured using, for example, an electron microscope.

The region defined by impurity region 37 and fourth groove 74 of light receiving layer 31 has a first electric resistance corresponding to the material of light receiving layer 31. The region defined by impurity region 37 and fourth groove 74 of light receiving layer 31 is an example of a first region. In addition, substantially no current flows through impurity region 37 and fourth groove 74, and impurity region 37 and fourth groove 74 have the second electric resistance higher than the first electric resistance. Impurity region 37 and fourth groove 74 are examples of a second region.

Light-receiving element 200 may not include metal film 55.

Other configurations of the second embodiment are the same as those of the first embodiment.

Next, a method for manufacturing light-receiving element 200 according to the second embodiment will be described.

First, as in the first embodiment, the processing up to the formation of first groove 71 and temporary groove 72X and the removal of deposits are performed (see FIG. 5). Next, Fe ions are implanted to form impurity region 37. For example, the dose amount of Fe is about 1×10¹⁶ atoms/cm². Next, as in the first embodiment, SiN film 192 is formed. Next, second groove 72 and fourth groove 74 are formed by dry etching.

Next, as in the first embodiment, the processing after the removal of the deposit (not shown) generated by the dry etching are performed.

In this way, light-receiving element 200 according to the second embodiment can be manufactured.

Impurity region 37 may be formed after fourth groove 74 is formed.

In light-receiving element 200, impurity region 37 absorbs light, but the movement of the electric charges from impurity region 37 to pixel 1 is reduced. Therefore, as in the first embodiment, the electric charges corresponding to the amount of light incident on each pixel 1 is easily obtained, and high detection accuracy is obtained.

Since fourth groove 74 is formed, light is not absorbed in fourth groove 74, and it is easy to further eliminate a decrease in detection accuracy accompanying generation of the electric charges in the vicinity of the boundary between adjacent pixels 1.

When impurity region 37 have a width of 1 μm to 5 μm, it is easy to form impurity region 37, and a region (first region) of light receiving layer 31 in which light can be absorbed is easily allocated to a sufficient size. Impurity region 37 may have a width of 1 μm to 3 μm, or 1 μm to 2 μm.

### Third Embodiment

Next, a third embodiment will be described. The third embodiment relates to a light detection device including light-receiving element 100 according to the first embodiment. FIG. 14 is a cross-sectional view of a light detection device according to the third embodiment.

A light detection device 300 according to the third embodiment includes light-receiving element 100 and readout circuit board (read out integrated circuit: ROIC) 400. Readout circuit board 400 includes a wiring substrate 410, a pixel electrode 452, a common electrode 451, and an under-fill resin layer 301. Pixel electrode 452 and common electrode 451 are arranged on one side of wiring substrate 410. Readout circuit board 400 includes a circuit for reading out a signal output from light-receiving element 100, for example, a multiplexer. Readout circuit board 400 is an example of a circuit board.

Light detection device 300 further includes a connection member 352 connecting p-electrode 52 and pixel electrode 452, and a connection member 351 connecting second n-electrode 53 and common electrode 451. Connection member 351 includes In-bump 61 and the In-bump provided on common electrode 451 of readout circuit board 400 before bonding. Connection member 352 includes In-bump 62 and the In-bump provided on pixel electrode 452 of readout circuit board 400 before bonding.

Under-fill resin layer 301 is provided between light-receiving element 100 and readout circuit board 400. Under-fill resin layer 301 is an example of a resin layer.

According to the third embodiment, since light-receiving element 100 is included, high detection accuracy may be obtained.

Light-receiving element 200 may be used instead of light-receiving element 100.

In the third embodiment, light-receiving element 100 may not be provided with metal film 55, and under-fill resin layer 301 may fill third groove 73. In this case, light incident on third groove 73 is absorbed by under-fill resin layer 301. That is, under-fill resin layer 301 functions as an example of a reflection film. Since under-fill resin layer 301 absorbs light, reflection of light in unspecified directions by readout circuit board 400 can be reduced.

Although embodiments have been described in detail above, the present disclosure is not limited to the specific embodiments, and various modifications and changes can be made within the scope described in the claims.

What is claimed is:

1. A light-receiving element comprising:
a substrate having a first main surface;
a first contact layer provided on the first main surface, the first contact layer being of a first conductivity type;
a light receiving layer provided on the first contact layer;
a pixel separation adjusting layer provided on the light receiving layer;
a second contact layer provided on the pixel separation adjusting layer, the second contact layer being of a second conductivity type;
a plurality of first grooves separating the second contact layer and the pixel separation adjusting layer into a plurality of pixels in a first direction parallel to the first main surface;
a second groove formed in the second contact layer, the pixel separation adjusting layer, and the light receiving layer on an outer side of the plurality of first grooves in the first direction, the second groove reaching the first contact layer;
a first electrode in contact at a bottom of the second groove with the first contact layer; and
a second electrode provided on the second contact layer,
wherein the light receiving layer has a first region provided for each of the pixels, the first region having a first electric resistance, and
wherein the light-receiving element has a second region provided between the first regions adjacent to each other, the second region having a second electric resistance higher than the first electric resistance.

2. The light-receiving element according to claim 1, wherein the second region has a width of 1 μm to 5 μm.

3. The light-receiving element according to claim 1, wherein the second region includes third grooves each being continuous with a bottom surface of a corresponding one of the first grooves and extending into the light receiving layer.

4. The light-receiving element according to claim 3, wherein the light-receiving element has a reflection film provided inside of each of the third grooves and configured to reflect, toward the first regions, light transmitted through the second region.

5. The light-receiving element according to claim 3, wherein the light-receiving element has an absorption film provided inside of each of the third grooves and configured to absorb light transmitted through the second region.

6. The light-receiving element according to claim 3, wherein the third grooves reach the first contact layer.

7. The light-receiving element according to claim 1, wherein the second region includes an impurity region containing an impurity at a higher concentration than the first regions.

8. The light-receiving element according to claim 7, wherein the light-receiving element includes fourth grooves each being continuous with a bottom surface of a corresponding one of the first grooves and reaching the impurity region.

9. A light detection device comprising:
the light-receiving element according to claim 1; and
a circuit board connected to the light-receiving element.

10. The light detection device according to claim 9,
wherein the light detection device has a resin layer provided between the light-receiving element and the circuit board.
